(19) United States
(12) Patent Application Publication
(10) Pub. No.: US 2013/0120080 A1
(43) Pub. Date: May 16, 2013

(54) SPURIOUS-MODE SUPPRESSION PIEZOELECTRIC RESONATOR DESIGN

(71) Applicants: Sang-June PARK, San Diego, CA (US); Jonghae KIM, San Diego, CA (US)

(72) Inventors: Sang-June PARK, San Diego, CA (US); Jonghae KIM, San Diego, CA (US)

(73) Assignee: QUALCOMM Incorporated, San Diego, CA (US)

(21) Appl. No.: 13/296,831

(22) Filed: Nov. 15, 2011

(51) Int. Cl. H03H 9/54

(52) U.S. Cl. CPC H03H 9/54
USPC 333/186; 29/25.35

(57) ABSTRACT

Provided are methods and apparatus to improve upon conventional piezoelectric resonators. Also provided are apparatus and methods to improve upon filters having piezoelectric resonators. In an example, a piezoelectric resonator includes a substrate, and a piezoelectric material disposed on the substrate. A first electrode and a second electrode are disposed on the piezoelectric material. The piezoelectric resonator has a passband, and a portion of the perimeter of the piezoelectric material is anchored to the substrate to suppress an in-band spurious mode of the piezoelectric material. The portion, if unanchored, would exhibit maximum, near-maximum, and/or excessive displacement deflection at resonance. The piezoelectric resonator can be integrated in a semiconductor die. Multiple filters having piezoelectric resonators with respective different passbands can be disposed on the substrate.

### FIELD OF THE INVENTION

This disclosure relates generally to electronics, and more specifically, but not exclusively, to apparatus and methods for improving piezoelectric resonators.

### BACKGROUND

A piezoelectric contour mode resonator (CMR) converts electrical energy into mechanical energy, attenuates some frequencies of the mechanical energy, and then converts the mechanical energy back into electrical energy. Electrical energy input to an input electrode contacting a piece of piezoelectric material (typically AN, ZnO, PZT, etc.) induces vibrations in the piezoelectric material. The piezoelectric material has a particular shape, and thus at least one resonant frequency at which a mechanical standing wave will occur in the piezoelectric material. An output electrode in contact with the piezoelectric material then converts the vibrations back into electrical energy. Among other resonance modes in the piezoelectric material, there are two distinct resonance modes in the piezoelectric material: 1) “d31 mode,” in which the electrical signal is applied in a first direction (e.g., a Z axis), and movement of the piezoelectric resonator is in a second direction perpendicular to the first direction (e.g., an X axis); and 2) “d33 mode,” in which a direction of both an applied electrical signal and movement of the piezoelectric resonator are the same. CMRs are conventionally employed in filters because contour mode vibrations can be excited using the d31 mode.

FIG. 1 depicts a conventional piezoelectric CMR 100, the conventional resonator's displacement during operation 105A-C, and the conventional piezoelectric resonator's frequency response 110. In a conventional CMR filter using a conventional piezoelectric CMR 100, in-band (i.e., whatever frequency spectrum is important in the filter design) spurious modes cause severe filter malfunctions because the in-band spurious modes lead to multiple resonant frequencies at different frequencies, as shown by the multiple closely-spaced resonance peaks in the conventional piezoelectric resonator's frequency response 110. In other words, the conventional CMR filter has multiple passbands, with some passbands occurring unintentionally. The filter malfunctions occur because piezoelectric CMRs are a mechanical resonator having narrow eigen-mode spacing, and thus spurious resonance modes. Accordingly, it is difficult to achieve a clean single fundamental resonance response from a conventional piezoelectric CMR. The spurious resonance modes greatly reduce the phase and magnitude responses of the conventional filter's fundamental resonance, which leads to high passband ripple, as well as poor out-of-band rejection. Effects of spurious modes are magnified when a high-frequency conventional piezoelectric CMR is used, because at higher frequencies, the mode spacing gets closer.

FIG. 2A depicts a conventional piezoelectric CMR filter 200 having an input interdigital electrode 205A, and an output interdigital electrode 205B, with each interdigital electrode 205A, 205B serving as an anchor for the piezoelectric portion 210 of the resonant device 200. In FIG. 2A, the input interdigital electrode 205A receives input electrical energy, and the piezoelectric portion 210 converts the electrical energy to mechanical vibrations of the piezoelectric portion 210. Then, the piezoelectric portion 210 converts the mechanical vibrations back to electric energy at the output interdigital electrode 205B. The conventional piezoelectric CMR filter 200 is designed with a length and width such that the center of the passband should by 700 MHz.

The FIG. 2B depicts the frequency response 250 of the conventional piezoelectric CMR filter 200. As can be seen in the frequency response 250, the passband of the conventional piezoelectric CMR filter 200 has several passbands, other than proper design passband centered at 700 MHz. A clean single passband cannot be achieved due to multiple spurious resonance modes of the conventional piezoelectric CMR filter 200.

Accordingly, there are long-felt industry needs for apparatus and methods to improve upon conventional piezoelectric resonators. There are also long-felt industry needs for apparatus and methods to improve upon filters having piezoelectric resonators, and devices in which piezoelectric resonators can be implemented.

### SUMMARY

Exemplary embodiments of the invention are directed to apparatus and methods for improving piezoelectric resonators, filters having piezoelectric resonators, and devices in which piezoelectric resonators can be implemented.

In exemplary embodiments, the piezoelectric resonators suppress spurious resonance modes and maintain a clean fundamental mode frequency response, because portions of the resonators that otherwise would exhibit maximum, near-maximum, and/or excessive displacement are anchored and/or removed and/or reshaped and/or loaded with extra material to remove and/or mitigate the displacement. The exemplary piezoelectric resonators are constructed with higher order mode spacing in one dimension to provide low motional resistance. When compared to conventional designs, the provided piezoelectric resonators have a different geometry at the boundary edges of a side of the piezoelectric resonator relating to the higher order mode. This different geometry suppresses detrimental in-band spurious modes. Filters having different passbands and center frequencies can be implemented on a single wafer using the piezoelectric resonators.

In an example, a piezoelectric resonator includes a substrate, and a piezoelectric material disposed on the substrate. A first electrode and a second electrode are disposed on the piezoelectric material. The piezoelectric resonator has a passband, and a portion of the perimeter of the piezoelectric material is anchored to the substrate to support the piezoelectric structures and/or suppress an in-band spurious mode of the piezoelectric material. Also provided can be means for anchoring the portion of the perimeter of the piezoelectric material to the substrate to suppress the in-band spurious mode of the piezoelectric material. The anchored portion of the perimeter, if unanchored, would exhibit maximum, near-maximum, and/or excessive displacement deflection at spurious mode resonance. The piezoelectric resonator can be integrated in a semiconductor die. A filter having a passband center frequency within a range between substantially 400 MHz and substantially 2700 MHz can have the piezoelectric resonator as a filtering component. Multiple filters having piezoelectric resonators with respective different passbands can be disposed on the substrate. A device, selected from the group consisting of a receiver, a set top box, a music player, a video player, an entertainment unit, a navigation device, a communications device, a personal digital assistant (PDA), a fixed location data unit, and a computer, can have the piezoelectric resonator as an integral component. Also provided in an example is a non-transitory computer-readable medium, having instructions stored thereon that, if executed by a lithographic device, cause the lithographic device to fabricate at least a part of the piezoelectric resonator.

In a further example, provided is a method for fabricating a piezoelectric resonator. A piezoelectric material is disposed on a substrate. First and second electrodes are disposed on the piezoelectric material. A portion of the perimeter of the piezoelectric material is anchored to the substrate to support the piezoelectric structures and/or suppress an in-band spurious mode of the piezoelectric material within the resonator's passband. The portion is selected such that, if unanchored, the portion exhibits maximum, near-maximum, and/or excessive deflection at spurious mode resonance. The passband's center frequency can be within a range between substantially 400 MHz and substantially 2700 MHz.

The foregoing has broadly outlined the features and technical advantages of the present teachings in order that the detailed description that follows may be better understood. Additional features and advantages are described herein, which form the subject of the claims. The conception and specific embodiments disclosed can be readily utilized as a basis for modifying or designing other structures for carrying out the same purposes of the present teachings. Such equivalent constructions do not depart from the technology of the teachings as set forth in the appended claims. The novel features which are believed to be characteristic of the teachings, both as to its organization and method of operation, together with further objects and advantages are better understood from the following description when considered in connection with the accompanying figures. Each of the figures is provided for the purpose of illustration and description only, and do not define limits of the present teachings.

### BRIEF DESCRIPTION OF THE DRAWINGS

The accompanying drawings are presented to describe examples of the present teachings, and are not provided as limitations.

FIG. 1 depicts a conventional piezoelectric resonator, the conventional resonator's displacement during operation, and the conventional piezoelectric resonator's frequency response.

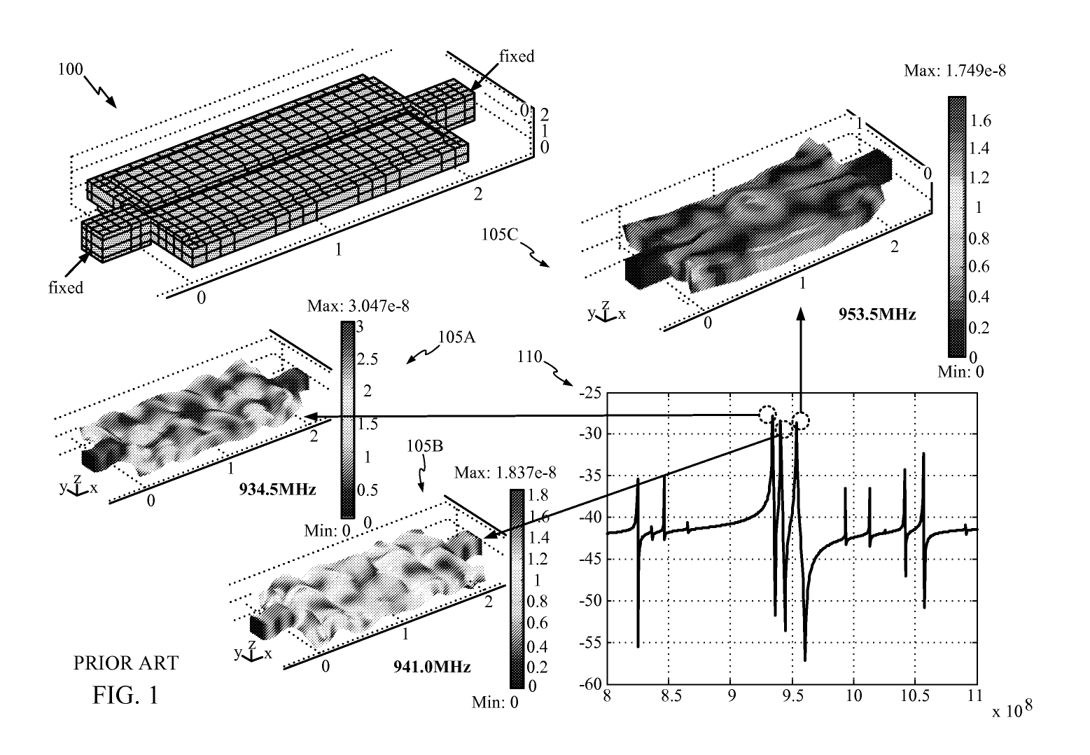

FIGS. 2A-B depict a second conventional piezoelectric resonator and the second conventional piezoelectric resonator's frequency response.

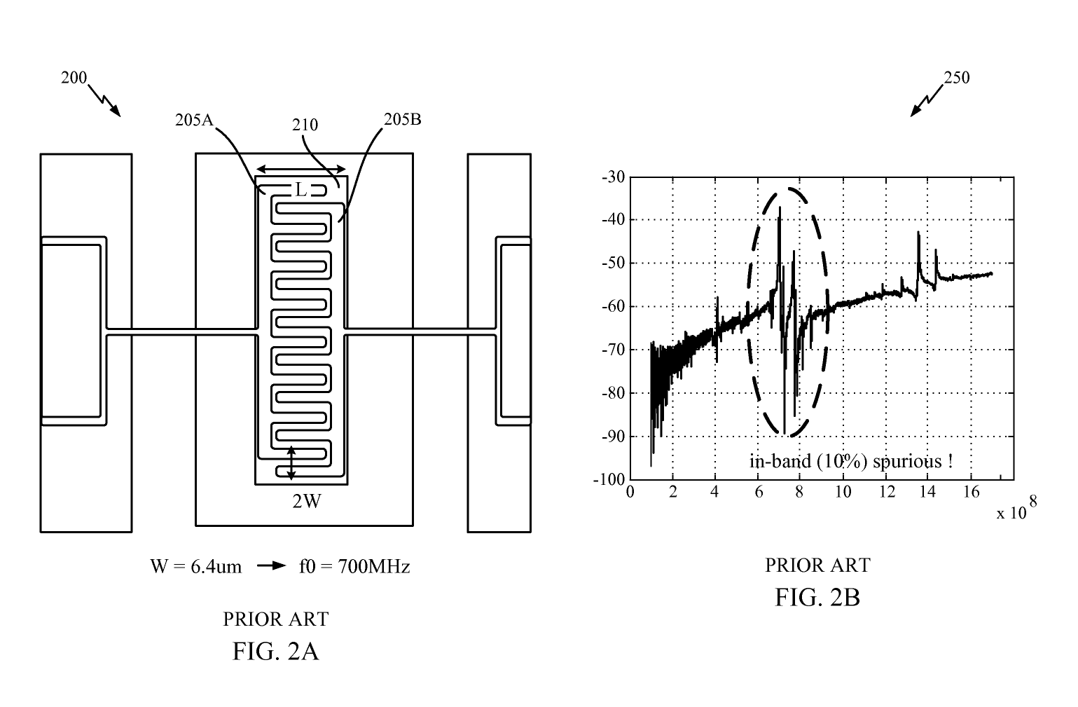

FIG. 3 depicts an exemplary communication system.

FIG. 4 depicts an exemplary CMR having an anchored portion, the CMR's displacement during operation, and the CMR's frequency response.

FIG. 5 depicts another exemplary CMR having an anchored portion, the CMR's displacement during operation, and the CMR's frequency response.

FIG. 6 depicts yet another exemplary CMR having an anchored portion CMR having an anchored portion, the CMR's displacement during operation, and the CMR's frequency response.

FIG. 7 depicts additional examples of the exemplary CMRs of FIGS. 4-6.

FIG. 8 depicts a method for fabricating a piezoelectric resonator.

In accordance with common practice, the various features illustrated in the drawings may not be drawn to scale. Accordingly, the dimensions of the various features may be arbitrarily expanded or reduced for clarity. In accordance with common practice, some of the drawings are simplified for clarity. Thus, the drawings may not depict all components of a given apparatus (e.g., device) or method. Finally, like reference numerals are used to denote like features throughout the specification and figures.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

It should be noted that the terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof. As employed herein two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

It should be understood that the term “signal” can include any signal such as a data signal, audio signal, video signal, multimedia signal. Information and signals can be represented using any of a variety of different technologies and techniques. For example, data, instructions, commands, information, signals, bits, symbols, and chips that can be referenced throughout this description can be represented by voltages, currents, electromagnetic waves, magnetic fields or particles, optical fields or particles, or any combination thereof.

It should be understood that any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element. Also, unless stated otherwise a set of elements can comprise one or more elements. In addition, terminology of the form “at least one of: A, B, or C” used in the description or the claims means “A or B or C or any combination of these elements.”

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Spatial descriptions (e.g., “top,” “middle,” “bottom,” “left,” “center,” “right,” “up,” “down,” “vertical,” “horizontal,” etc.) used herein are for illustrative purposes only, and are not limiting descriptors. Practical implementations of the structures described hereby can be spatially arranged in any orientation providing the functions described hereby. In addition, in using the term “adjacent” herein to describe a spatial relationship between integrated circuit elements, the adjacent integrated circuit elements need not be in direct physical contact, and other integrated circuit elements can be located between the adjacent integrated circuit elements.

Further, many embodiments are described in terms of sequences of actions to be performed by, for example, elements of a computing and/or lithographic device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

### Introduction

In exemplary embodiments, the piezoelectric resonators suppress spurious resonance modes and maintain a clean fundamental mode frequency response, because portions of the resonators that otherwise would exhibit maximum, near-maximum, and/or excessive displacement are anchored and/or reshaped and/or loaded with extra material to remove and/or mitigate the displacement. The exemplary piezoelectric resonators are constructed with higher order mode spacing in one dimension to provide low motional resistance. When compared to conventional designs, the provided piezoelectric resonators have a different geometry at the boundary edges of a side of the piezoelectric resonator relating to the higher order mode. This different geometry suppresses detrimental in-band spurious modes. Filters having different passbands and center frequencies can be implemented on a single wafer using the piezoelectric resonators.

In an example, a piezoelectric resonator includes a substrate, and a piezoelectric material disposed on the substrate. A first electrode and a second electrode are disposed in contact with the piezoelectric material. The piezoelectric resonator has a passband, and a portion of the perimeter of the piezoelectric material is anchored to the substrate to suppress an in-band spurious mode of the piezoelectric material. The portion, if unanchored, would exhibit maximum deflection at resonance.

### Description of the Figures

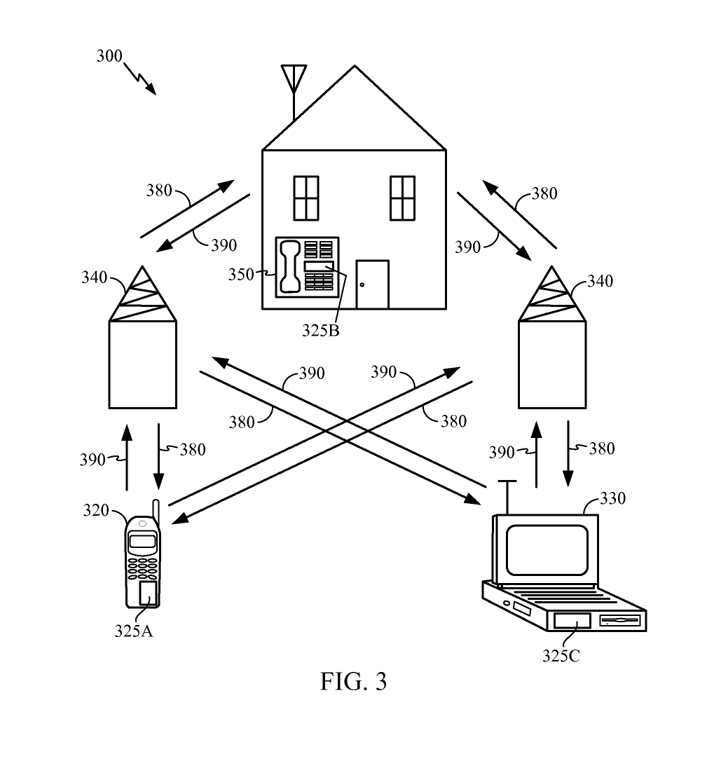

FIG. 3 depicts an exemplary communication system 300 in which an embodiment of the disclosure may be advantageously employed. For purposes of illustration, FIG. 3 shows three remote units 320, 330, and 350 and two base stations 340. It will be recognized that conventional wireless communication systems may have many more remote units and base stations. The remote units 320, 330, and 350 include at least a part of an embodiment 325A-C of the disclosure as discussed further below. FIG. 3 shows forward link signals 380 from the base stations 340 and the remote units 320, 330, and 350, as well as reverse link signals 390 from the remote units 320, 330, and 350 to the base stations 340.

In FIG. 3, the remote unit 320 is shown as a mobile telephone, the remote unit 330 is shown as a portable computer, and the remote unit 350 is shown as a fixed location remote unit in a wireless local loop system. For example, the remote units may be transmitters, receivers, mobile phones, hand-held personal communication systems (PCS) units, portable data units such as personal data assistants, navigation devices (such as GPS enabled devices), set top boxes, music players, video players, entertainment units, fixed location data units (e.g., meter reading equipment), or any other device that stores or retrieves data or computer instructions, or any combination thereof. Although FIG. 3 illustrates remote units according to the teachings of the disclosure, the disclosure is not limited to these exemplary illustrated units. Embodiments of the disclosure may be suitably employed in any device.

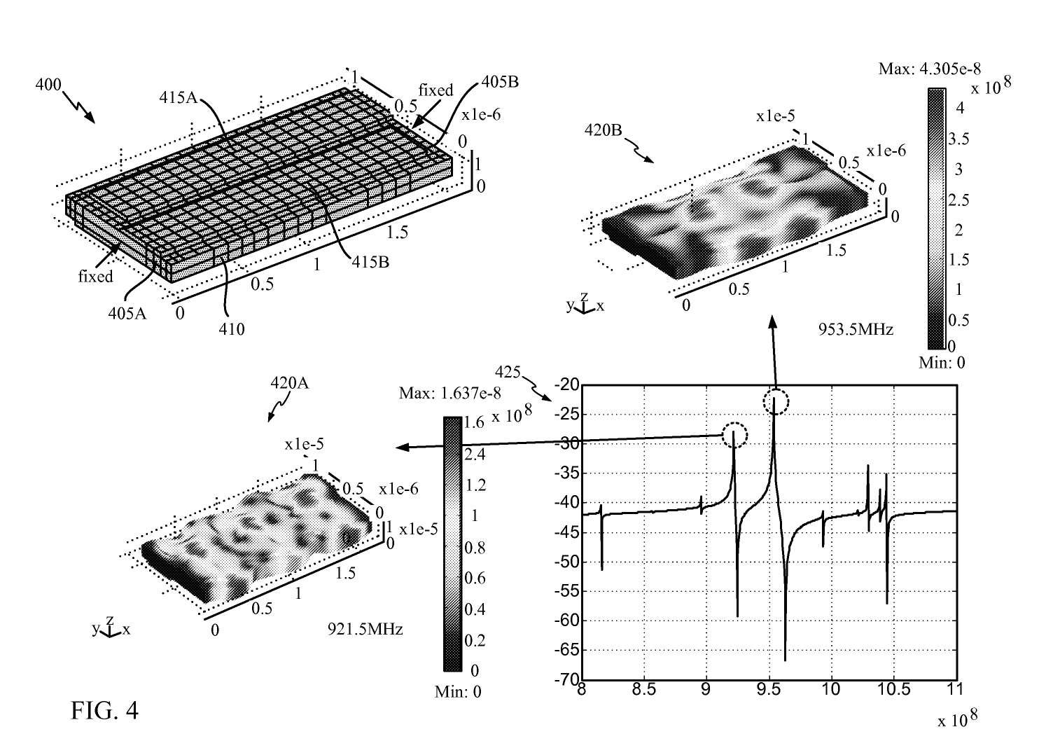

FIGS. 4-7 depict exemplary contour mode resonators (CMRs) according to embodiments of the invention, the exemplary CMRs' respective displacement during operation, and the exemplary CMRs' respective frequency response. The exemplary CMRs in FIGS. 4-7 enable implementing communication devices having lower complexity, a simpler design, and/or a compact form factor. The exemplary CMRs in FIGS. 4-7 also enable fabricating arrays of high-performance filters with different passband frequencies, on a single chip.

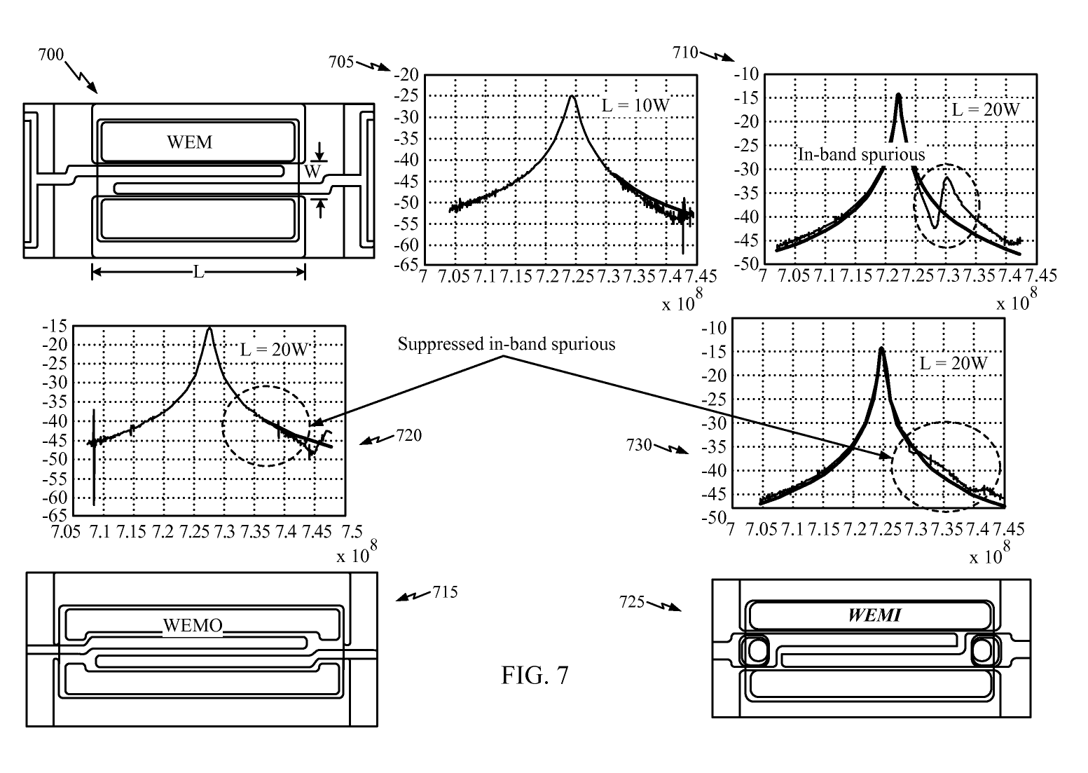

FIG. 4 depicts an exemplary first CMR 400. In the first CMR 400, two substantially opposing sides 405A, 405B of a piezoelectric material 410 are anchored (i.e., fixed) to a substrate. In an example, the opposing sides 405A, 405B are anchored substantially in their entirety. The anchored portions of the first CMR 400, if unanchored, would exhibit maximum, near-maximum, and/or excessive displacement deflection at resonance. A first electrode 415A and a second electrode 415B are in contact with a surface substantially perpendicular to the anchored opposing sides 405A, 405B. In an example, the first CMR 400 is operated in a d33 resonant mode. Another view of the first CMR 400 can be found in FIG. 7.

FIG. 4 also depicts the first CMR's displacement during operation 420A, 420B. The displacement images 420A, 420B reflect that the first CMR 400 has substantially opposing sides 405A, 405B that are anchored. When compared to the conventional resonator's displacement during operation 105A-C, the first CMR's displacement during operation 420A, 420B shows that the first CMR 400 has displacement that is more constrained and controlled, to mitigate spurious resonance modes. The effects of anchoring the first CMR 400 are reflected in the frequency response 425 of the first CMR 400, which, when compared to the conventional piezoelectric resonator's frequency response 110, shows that the first CMR 400 mitigates spurious resonance modes, and thus has fewer passbands.

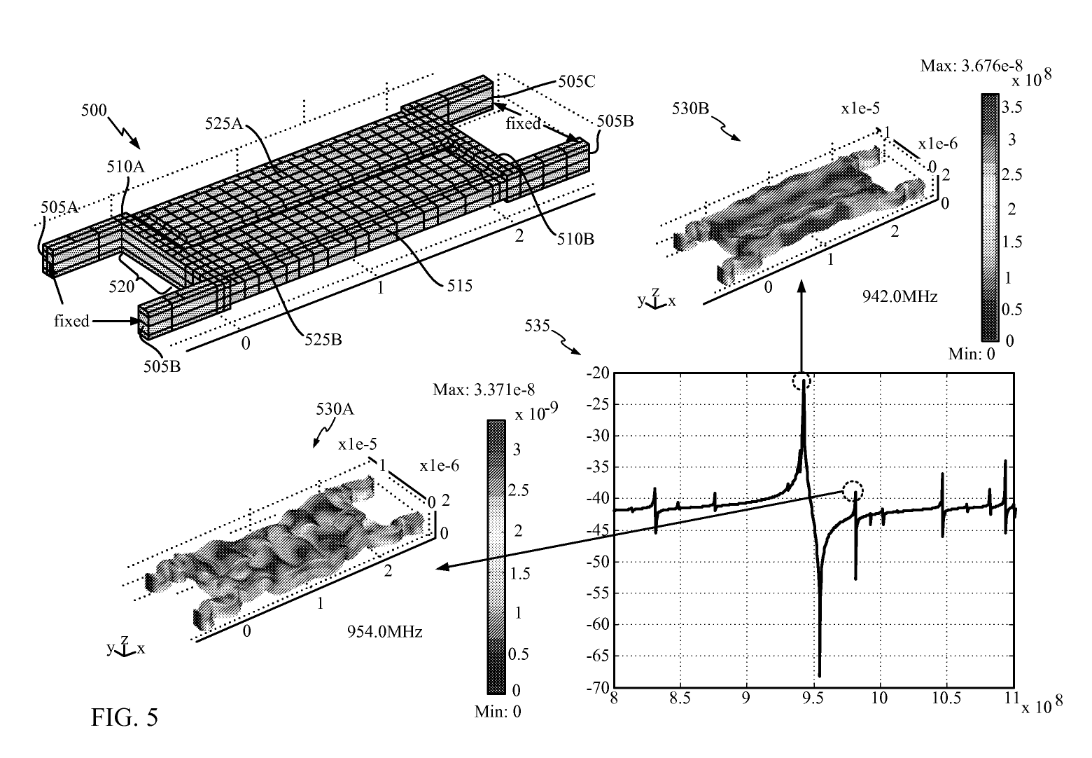

FIG. 5 depicts an exemplary second CMR 500. In the second CMR 500, the outer portions 505A-D of two substantially opposing sides 510A, 510B of a piezoelectric material 515 are anchored (i.e., fixed) to a substrate, while an inner portion 520 of the two substantially opposing sides 510A, 510B is not anchored. In an example, the anchored portions are extended from the bulk of the piezoelectric material 515. The anchored portions of the second CMR 500, if unanchored, would exhibit maximum, near-maximum, and/or excessive displacement deflection at resonance. A first electrode 525A and a second electrode 525B are in contact with a surface substantially perpendicular to the anchored opposing sides 510A, 510B. In an example, the second CMR 500 is operated in a d33 resonant mode. Another view of the second CMR 500 can be found in FIG. 7.

FIG. 5 also depicts the second CMR's displacement during operation 530A, 530B. The displacement images 530A, 530B reflect that the second CMR 500 has outer portions of substantially opposing sides 510A, 510B that are anchored. When compared to the conventional resonator's displacement during operation 105A-C, the second CMR's displacement during operation 530A, 530B shows that the second CMR 500 has displacement that is more constrained and controlled, to mitigate spurious resonance modes. The effects of anchoring the second CMR 500 are reflected in the frequency response 535 of the second CMR 500, which, when compared to the conventional piezoelectric resonator's frequency response 110, shows that the second CMR 500 mitigates spurious resonance modes, and thus has fewer passbands.

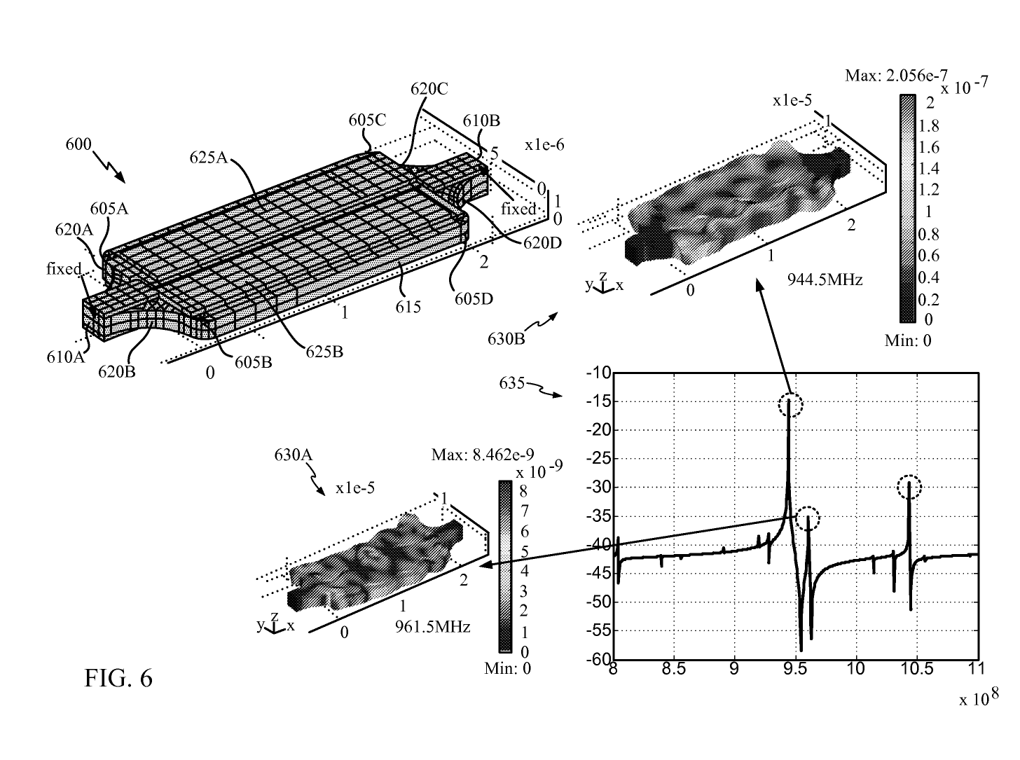

FIG. 6 depicts an exemplary third CMR 600. In the third CMR 600, the outer portions 605A-D of two substantially opposing sides 610A, 610B of a piezoelectric material 615 are anchored (i.e., fixed) to a substrate via respective fillets 620A-D. The anchored portions of the third CMR 600, if unanchored, would exhibit maximum, near-maximum, and/or excessive displacement deflection at resonance. A first electrode 625A and a second electrode 625B are in contact with a surface substantially perpendicular to the anchored opposing sides 610A, 610B. In an example, the third CMR 600 is operated in a d33 resonant mode. Another view of the third CMR 600 can be found in FIG. 7.

FIG. 6 also depicts the second CMR's displacement during operation 630A, 630B. The displacement images 630A, 630B reflect that the third CMR 600 has outer portions of substantially opposing sides 610A, 610B that are anchored. When compared to the conventional resonator's displacement during operation 105A-C, the third CMR's displacement during operation 630A, 630B shows that the third CMR 600 has displacement that is more constrained and controlled, to mitigate spurious resonance modes. The effects of anchoring the third CMR 600 are reflected in the frequency response 635 of the third CMR 600, which, when compared to the conventional piezoelectric resonator's frequency response 110, shows that the third CMR 600 mitigates spurious resonance modes, and thus has fewer passbands.

FIG. 7 depicts additional examples of the exemplary CMRs of FIGS. 4-6. A “with extension mode” (WEM) device 700 is an example of the first CMR 400. The WEM device 700 has a first frequency response 705 when the length of the WEM device 700 is equal to ten times the width of the WEM device 700, which, when compared to conventional devices, shows mitigation of spurious resonance modes and a single distinct passband. When the envelope of the WEM device is pushed to an extreme, and the length of the WEM device 700 is equal to twenty times the width of the WEM device 700, the second frequency response 710 results, which starts to exhibit an in-band spurious mode.

FIG. 7 also depicts a “with extension mode, O-shape” (WEMO) device 715, which is an example of the second CMR 500. The WEMO device 715 has a frequency response 720 when the length of the WEMO device 715 is equal to twenty times the width of the WEMO device 715, which, when compared to conventional devices, shows mitigation of spurious resonance modes and a single distinct passband, as well as suppression of in-band spurious resonant modes.

FIG. 7 further depicts a “with extension mode, I-shape” (WEMI) device 725, which is an example of the third CMR 600. The WEMI device 725 has a frequency response 730 when the length of the WEMI device 725 is equal to twenty times the width of the WEMO device 715, which, when compared to conventional devices, shows mitigation of spurious resonance modes and a single distinct passband, as well as suppression of in-band spurious resonant modes.

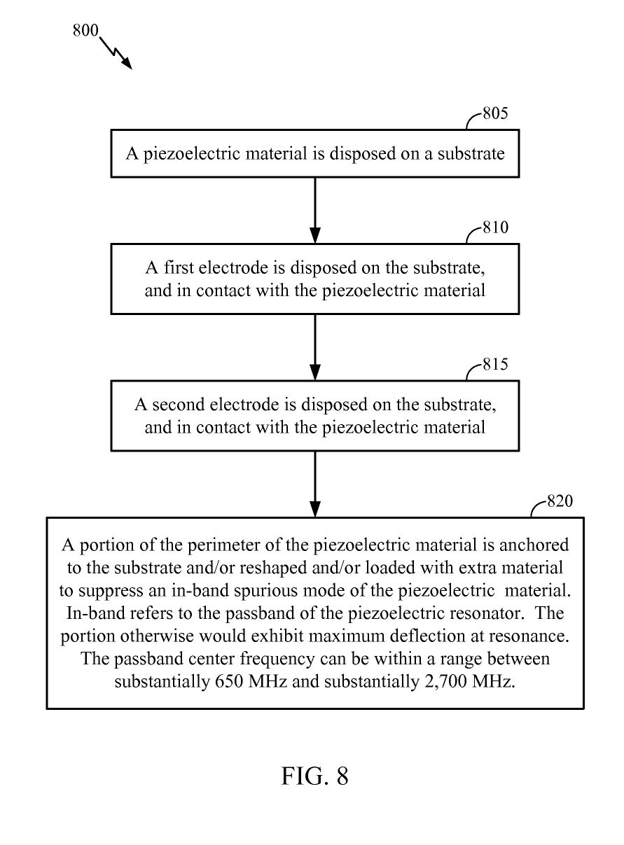

FIG. 8 depicts a method 800 for fabricating a piezoelectric resonator. The method 800 can be implemented using a lithographic device.

In step 805, a piezoelectric material is deposited on a substrate.

In step 810, a first electrode is disposed on the substrate, and in contact with the piezoelectric material.

In step 815, a second electrode is disposed on the substrate, and in contact with the piezoelectric material.

In step 820, a portion of the perimeter of the piezoelectric material is anchored to the substrate and/or reshaped and/or loaded with extra material to suppress an in-band spurious mode of the piezoelectric material. In-band refers to the passband of the piezoelectric resonator. The portion otherwise would otherwise exhibit maximum, near-maximum, and/or excessive displacement deflection at resonance. The passband's center frequency can be within a range between substantially 400 MHz and substantially 2700 MHz.

### CONCLUSION

Those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

In some aspects, the teachings herein can be employed in a multiple-access system capable of supporting communication with multiple users by sharing the available system resources (e.g., by specifying one or more of bandwidth, transmit power, coding, interleaving, and so on). For example, the teachings herein can be applied to any one or combinations of the following technologies: Code Division Multiple Access (CDMA) systems, Multiple-Carrier CDMA (MCCDMA), Wideband CDMA (W-CDMA), High-Speed Packet Access (HSPA, HSPA+) systems, Time Division Multiple Access (TDMA) systems, Frequency Division Multiple Access (FDMA) systems, Single-Carrier FDMA (SC-FDMA) systems, Orthogonal Frequency Division Multiple Access (OFDMA) systems, or other multiple access techniques. A wireless communication system employing the teachings herein can be designed to implement one or more standards, such as IS-95, cdma2000, IS-856, W-CDMA, TDSCDMA, and other standards. A CDMA network can implement a radio technology such as Universal Terrestrial Radio Access (UTRA), cdma2000, or some other technology. UTRA includes W-CDMA and Low Chip Rate (LCR). The cdma2000 technology covers IS-2000, IS-95 and IS-856 standards. A TDMA network can implement a radio technology such as Global System for Mobile Communications (GSM). An OFDMA network can implement a radio technology such as Evolved UTRA (E-UTRA), IEEE 802.11, IEEE 802.16, IEEE 802.20, Flash-OFDM.RTM., etc. UTRA, E-UTRA, and GSM are part of Universal Mobile Telecommunication System (UMTS). The teachings herein can be implemented in a 3GPP Long Term Evolution (LTE) system, an Ultra-Mobile Broadband (UMB) system, and other types of systems. LTE is a release of UMTS that uses E-UTRA. UTRA, E-UTRA, GSM, UMTS and LTE are described in documents from an organization named “3rd Generation Partnership Project” (3GPP), while cdma2000 is described in documents from an organization named “3rd Generation Partnership Project 2” (3GPP2). Although certain aspects of the disclosure can be described using 3GPP terminology, it is to be understood that the teachings herein can be applied to 3GPP (e.g., Re199, Re15, Re16, Re17) technology, as well as 3GPP2 (e.g., 1xRTT, 1xEV-DO Re1O, RevA, RevB) technology and other technologies. The techniques can be used in emerging and future networks and interfaces, including Long Term Evolution (LTE).

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

An embodiment of the invention can include a computer readable media embodying a method described herein and/or a method for fabricating at least a part of a device described herein. Accordingly, the invention is not limited to illustrated examples and any means for performing the functionality described herein are included in embodiments of the invention.

The disclosed devices and methods can be designed and can be configured into GDSII and GERBER computer files, stored on a computer readable media. These files are in turn provided to fabrication handlers who fabricate devices, based on these files, with a lithographic device. The resulting products are semiconductor wafers that are then cut into semiconductor die and packaged into a semiconductor chip. The chips are then employed in devices described herein.

Nothing that has been stated or illustrated is intended to cause a dedication of any component, step, feature, object, benefit, advantage, or equivalent to the public, regardless of whether it is recited in the claims.

While this disclosure shows exemplary embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order.

What is claimed is:

1. A piezoelectric resonator, comprising:
a substrate;
a piezoelectric material;
a first electrode coupled to the piezoelectric material; and
a second electrode coupled to the piezoelectric material,
wherein the piezoelectric resonator has a passband, and a portion of the perimeter of the piezoelectric material is anchored to the substrate to suppress an in-band spurious mode of the piezoelectric material, and
wherein the portion, if unanchored, would exhibit substantially maximum deflection at resonance.

2. The piezoelectric resonator of claim 1, wherein the piezoelectric resonator is integrated in a semiconductor die.

3. A filter comprising the piezoelectric resonator of claim 1.

4. The filter of claim 3, wherein the passband's center frequency is within a range between substantially 400 MHz and substantially 2700 MHz.

5. A plurality of filters disposed on a substrate, each filter comprising a piezoelectric resonator of claim 1, wherein each piezoelectric resonator has a different passband.

6. The piezoelectric resonator of claim 1, further comprising a device, selected from the group consisting of a receiver, a set top box, a music player, a video player, an entertainment unit, a navigation device, a communications device, a personal digital assistant (PDA), a fixed location data unit, and a computer, into which the piezoelectric resonator is integrated.

7. A non-transitory computer-readable medium, comprising instructions stored thereon that, if executed by a lithographic device, cause the lithographic device to fabricate at least a part of a piezoelectric resonator, comprising:
a substrate;
a piezoelectric material;
a first electrode coupled to the piezoelectric material; and
a second electrode coupled to the piezoelectric material,
wherein the piezoelectric resonator has a passband, and a portion of the perimeter of the piezoelectric material is anchored to the substrate to suppress an in-band spurious mode of the piezoelectric material, and
wherein the portion, if unanchored, would exhibit maximum deflection at resonance.

8. The non-transitory computer-readable medium of claim 7, wherein the piezoelectric resonator is fabricated in a semiconductor die.

9. The non-transitory computer-readable medium of claim 7, further comprising instructions stored thereon that, if executed by a lithographic device, cause the lithographic device to fabricate at least a part of a filter comprising the piezoelectric resonator of claim 7.

10. The non-transitory computer-readable medium of claim 7, wherein the passband's center frequency is within a range between substantially 400 MHz and substantially 2700 MHz.

11. The non-transitory computer-readable medium of claim 7, further comprising instructions stored thereon that, if executed by a lithographic device, cause the lithographic device to fabricate at least a part of a plurality of filters disposed on a substrate, each filter comprising a piezoelectric resonator of claim 7, wherein each piezoelectric resonator has a different passband.

12. A method for fabricating a piezoelectric resonator, comprising:
disposing a piezoelectric material on a substrate;
disposing a first electrode on the substrate, and in contact with the piezoelectric material;
disposing a second electrode on the substrate, and in contact with the piezoelectric material,
wherein the piezoelectric resonator has a passband; and
anchoring a portion of the perimeter of the piezoelectric material to the substrate to suppress an in-band spurious mode of the piezoelectric material, wherein the portion, if unanchored, would exhibit maximum deflection at resonance.

13. The method of claim 12, wherein the passband's center frequency is within a range between substantially 400 MHz and substantially 2700 MHz.

14. A piezoelectric resonator, comprising:
a substrate;
a piezoelectric material;
a first electrode coupled to the piezoelectric material;
a second electrode coupled to the piezoelectric material,
wherein the piezoelectric resonator has a passband, and means for anchoring a portion of the perimeter of the piezoelectric material to the substrate to suppress an in-band spurious mode of the piezoelectric material,
wherein the portion, if unanchored, would exhibit maximum deflection at resonance.

15. The piezoelectric resonator of claim 14, wherein the resonator is integrated in a semiconductor die.

16. A filter comprising the piezoelectric resonator of claim 14.

17. The filter of claim 16, wherein the passband's center frequency is within a range between substantially 400 MHz and substantially 2700 MHz.

18. A plurality of filters disposed on a substrate, each filter comprising a piezoelectric resonator of claim 14, wherein each piezoelectric resonator has a different passband.

19. The piezoelectric resonator of claim 14, further comprising a device, selected from the group consisting of a receiver, a set top box, a music player, a video player, an entertainment unit, a navigation device, a communications device, a personal digital assistant (PDA), a fixed location data unit, and a computer, into which the piezoelectric resonator is integrated.

20. A piezoelectric resonator, comprising:
a substrate;
a piezoelectric material;
a first electrode coupled to the piezoelectric material; and
a second electrode coupled to the piezoelectric material,
wherein the piezoelectric resonator has a passband, and a portion of the perimeter of the piezoelectric material is removed to suppress an in-band spurious mode of the piezoelectric material, and
wherein the portion, if unanchored, would exhibit substantially maximum deflection at resonance.

21. A piezoelectric resonator, comprising:
a substrate;
a piezoelectric material;
a first electrode coupled to the piezoelectric material; and
a second electrode coupled to the piezoelectric material,
wherein the piezoelectric resonator has a passband, and a portion of the perimeter of the piezoelectric material is reshaped to suppress an in-band spurious mode of the piezoelectric material, and
wherein the portion, if unanchored, would exhibit substantially maximum deflection at resonance.

22. A piezoelectric resonator, comprising:
a substrate;
a piezoelectric material;
a first electrode coupled to the piezoelectric material; and
a second electrode coupled to the piezoelectric material,
wherein the piezoelectric resonator has a passband, and a portion of the perimeter of the piezoelectric material is loaded with extra material to suppress an in-band spurious mode of the piezoelectric material, and
wherein the portion, if unanchored, would exhibit substantially maximum deflection at resonance.
